(19) United States
(12) Patent Application Publication
(10) Pub. No.: US 2015/0123661 A1
(43) Pub. Date: May 7, 2015

(54) MAGNETIC RESONANCE IMAGING APPARATUS AND IMAGING CONTROL METHOD THEREOF

(71) Applicants: KABUSHIKI KAISHA TOSHIBA, Tokyo (JP); TOSHIBA MEDICAL SYSTEMS CORPORATION, Otawara-shi Tochigi (JP)

(72) Inventors: Masao YUI, Otawara Tochigi (JP); Seiji NOZAKI, Otawara Tochigi (JP)

(21) Appl. No.: 14/520,685

(22) Filed: Oct. 22, 2014

(30) Foreign Application Priority Data
Nov. 1, 2013 (JP) 2013-228614

(51) Int. Cl. G01R 33/54; G01R 33/56; G01R 33/385

(52) U.S. Cl. CPC G01R 33/543; G01R 33/3856; G01R 33/546; G01R 33/56
USPC 324/318

(57) ABSTRACT

A magnetic resonance imaging apparatus according to an embodiment includes a predicting unit and an imaging control unit. The predicting unit predicts a temperature change in a gradient coil at the time a pulse sequence is executed, based on temperature of the gradient coil and current waveform information on a gradient magnetic field pulse, before the pulse sequence is executed. The imaging control unit controls execution of the pulse sequence in accordance with a result of the prediction. The predicting unit predicts the temperature change by separating heat generation in the gradient coil into a component equivalent to heat generation as an electrical resistance of the gradient coil and a component equivalent to heat generation as an inductive circuit induced by switching of the gradient coil.

### CROSS-REFERENCE TO RELATED APPLICATIONS

This application is based upon and claims the benefit of priority from Japanese Patent Application No. 2013-228614, filed on Nov. 1, 2013, the entire contents of all of which are incorporated herein by reference.

### FIELD

Embodiments described herein relate generally to a magnetic resonance imaging apparatus and an imaging control method thereof.

### BACKGROUND

A magnetic resonance imaging apparatus (hereinafter, referred to as an MRI apparatus, as appropriate) is an apparatus that causes nuclear magnetic resonance by using three types of magnetic fields, which are a static magnetic field, a gradient magnetic field, and a high-frequency magnetic field, and obtains an image of a subject by reconstruction processing of a resonance signal. The gradient magnetic field out of the foregoing is generated in a pulsed manner with a gradient coil and a gradient amplifier, and assumes a role of selecting resonating nuclear spin and adding a quantity dependent on spatial location to the phase of the resonance signal. The intensity, application time, and frequency of the gradient magnetic field pulse directly affect the speed and time efficiency of generating and reading the resonance signal. Thus, for the progress in the speed-up and high-functionalization of MRI apparatuses, improvements in the performance of a gradient subsystem, for example, the technology development implementing high intensity, rapid switching, and high availability have made great contributions.

Among them, there is a method referred to as “burst driving” that temporarily enhances high intensity and high availability. In an examination by an MRI apparatus, in general, a plurality of contrast images in combination are image-interpreted and thus different types of images are imaged. Thus, there are variations present in types of imaging and purposes of imaging, and that causes highs and lows to be present in the availability of the gradient subsystem within a single examination and causes the fluctuation thereof to be present among different examinations. While the average value of the availability in normal examinations is low, the need to generate a gradient magnetic field at a high availability in the short term is high. In the examination by the MRI apparatus, desirable is to protect the MRI apparatus and to avoid a situation in which a normal progress of examination is interrupted by a rise in temperature while permitting a temporary rise in temperature by such burst driving.

### BRIEF DESCRIPTION OF THE DRAWINGS

FIG. 1 is a functional block diagram illustrating the configuration of an MRI apparatus according to a first embodiment;

FIG. 2 is a diagram for explaining an outline of imaging control based on a temperature change prediction in the first embodiment;

FIG. 3 is a diagram for explaining the derivation of coefficient matrices in the first embodiment;

FIGS. 4A to 4D are diagrams for explaining reference imaging in the first embodiment;

FIG. 5 is a flowchart illustrating a processing procedure of an examination performed in the first embodiment; and

FIGS. 6A and 6B are diagrams for explaining one example of the temperature change prediction in the first embodiment.

### DETAILED DESCRIPTION

A magnetic resonance imaging apparatus according to an embodiment includes a predicting unit and an imaging control unit. The predicting unit predicts a temperature change in a gradient coil at the time a pulse sequence is executed, based on temperature of the gradient coil and current waveform information on a gradient magnetic field pulse, before the pulse sequence is executed. The imaging control unit controls execution of the pulse sequence in accordance with a result of the prediction. The predicting unit predicts the temperature change by separating heat generation in the gradient coil into a component equivalent to heat generation as an electrical resistance of the gradient coil and a component equivalent to heat generation as an inductive circuit induced by switching of the gradient coil.

With reference to the accompanying drawings, the following describes a magnetic resonance imaging apparatus and an imaging control method thereof according to exemplary embodiments. Note that the embodiments are not to be limited to the following embodiments. Furthermore, the content described in each of the embodiments can be applied, in principle, to the other embodiments in the same manner.

### First Embodiment

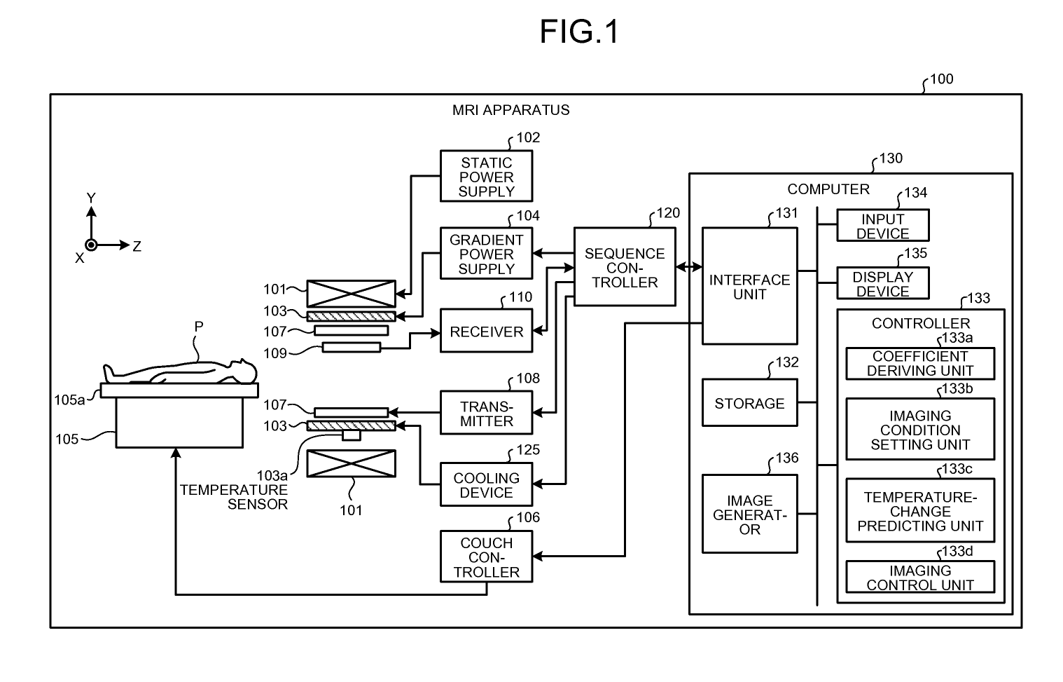

FIG. 1 is a functional block diagram illustrating the configuration of an MRI apparatus 100 according to a first embodiment. As illustrated in FIG. 1, the MRI apparatus 100 includes a static magnet 101, a static power supply 102, a gradient coil 103, a gradient power supply 104, a couch 105, a couch controller 106, a transmitting coil 107, a transmitter 108, a receiving coil 109, a receiver 110, a sequence controller 120, a cooling device 125, and a computer 130. Note that the MRI apparatus 100 does not include a subject P (for example, a human body). Furthermore, the configuration illustrated in FIG. 1 is merely an example. For example, the sequence controller 120 and the various units in the computer 130 may be configured to be integrated or distributed as appropriate.

The static magnet 101 is a magnet formed in a hollow cylindrical shape, and in a void space on the inner side thereof, generates a static magnetic field. The static magnet 101 is a superconducting magnet, for example, and is excited by receiving the supply of electrical current from the static power supply 102. The static power supply 102 supplies the current to the static magnet 101. The static magnet 101 may be a permanent magnet, and in this case, the MRI apparatus 100 may not need to include the static power supply 102. The static power supply 102 may be provided separately from the MRI apparatus 100.

The gradient coil 103 is a coil formed in a hollow cylindrical shape and is disposed on the inner side of the static magnet 101. The gradient coil 103 is formed with a combination of three coils corresponding to respective axes of X, Y, and Z which are orthogonal to one another. The three coils each receive a gradient magnetic field pulse individually from the gradient power supply 104, and generate a gradient magnetic field the magnetic field intensity of which varies along the respective axes of X, Y, and Z. The gradient magnetic fields on the respective axes of X, Y, and Z generated by the gradient coil 103 are a slice-encoding gradient magnetic field Gs, a phase-encoding gradient magnetic field Ge, and a read-out gradient magnetic field Gr, for example.

The gradient coil 103 further includes a temperature sensor 103a. The temperature sensor 103a is disposed, in the gradient coil 103, at a representative point such as a portion at which the temperature is likely to rise and a portion at which the heat is likely to accumulate, and measures the temperature. The timing of reading out the temperature from the temperature sensor 103a is adjusted to avoid errors attributable to the irradiation of radio frequency (RF) pulses. For example, a semiconductor device is used as the temperature sensor 103a, and the data read out at the timing of the irradiation of RF pulses being not present is defined as valid temperature measurement data. The gradient power supply 104 supplies the gradient magnetic field pulses to the gradient coil 103.

The couch 105 includes a couchtop 105a on which the subject P is placed, and under the control of the couch controller 106, inserts the couchtop 105a, in a state of the subject P being placed thereon, into a cavity (imaging opening) of the gradient coil 103. Generally, the couch 105 is installed such that the longitudinal direction thereof is parallel to the central axis of the static magnet 101. The couch controller 106, under the control of the computer 130, drives the couch 105 and moves the couchtop 105a in the longitudinal direction and up-and-down direction thereof.

The transmitting coil 107 is disposed on the inner side of the gradient coil 103, and by receiving the supply of RF pulses from the transmitter 108, generates a high-frequency magnetic field. The transmitter 108 supplies the RF pulses corresponding to a Larmor frequency, which is determined by the type of intended atom and the intensity of the magnetic field, to the transmitting coil 107.

The receiving coil 109 is disposed on the inner side of the gradient coil 103 and receives a magnetic resonance signal (hereinafter, referred to as an MR signal, as appropriate) emitted from the subject P by the influence of the high-frequency magnetic field. Upon receiving the MR signal, the receiving coil 109 outputs the received MR signal to the receiver 110.

Note that the transmitting coil 107 and the receiving coil 109 in the foregoing are mere examples. Out of a coil provided with only a transmitting function, a coil provided with only a receiving function, and a coil provided with a transmitting and receiving function, the transmitting and receiving coils only need to be configured with one or a combination of the foregoing.

The receiver 110 detects the MR signal output from the receiving coil 109, and based on the detected MR signal, generates MR data. Specifically, the receiver 110 generates the MR data by performing digital conversion on the MR signal output from the receiving coil 109. Furthermore, the receiver 110 sends the generated MR data to the sequence controller 120. The receiver 110 may be provided on a gantry device side on which the static magnet 101, the gradient coil 103, and others are provided.

The sequence controller 120 perform imaging of the subject P by driving the gradient power supply 104, the transmitter 108, and the receiver 110 based on sequence information sent from the computer 130. The sequence information here is the information that defines a procedure to perform imaging. The sequence information defines the current waveform information on a gradient magnetic field pulse (more specifically, the intensity, application time, timing of application, and others of the current), the current waveform information on RF pulses (more specifically, the intensity, application time, timing of application, and others of the current), the timing of the receiver 110 detecting the MR signal, and others. The sequence controller 120 is an electronic circuit such as an integrated circuit such as an application specific integrated circuit (ASIC) and a field programmable gate array (FPGA), a central processing unit (CPU), and a micro processing unit (MPU), for example.

As a result of driving the gradient power supply 104, the transmitter 108, and the receiver 110 so as to perform imaging of the subject P, when the sequence controller 120 receives the MR data from the receiver 110, the sequence controller 120 transfers the received MR data to the computer 130. The sequence controller 120 further controls the cooling device 125.

The cooling device 125 cools the gradient coil 103 by circulating a refrigerant (for example, water) in a cooling tube provided on the gradient coil 103. The cooling device 125 and the cooling tube are connected with a cooling pipe (omitted to depict), and the gradient coil 103 is cooled by the refrigerant flowing through inside the cooling tube and the cooling pipe. The refrigerant warmed up by the gradient coil 103 is delivered to the cooling device 125 again, and is then cooled down to a given temperature and supplied again to the gradient coil 103.

The computer 130 performs an overall control of the MRI apparatus 100, generation of images, and others. The computer 130 includes an interface unit 131, a storage 132, a controller 133, an input device 134, a display device 135, and an image generator 136.

The interface unit 131 sends the sequence information to the sequence controller 120 and receives the MR data from the sequence controller 120. Furthermore, upon receiving the MR data, the interface unit 131 stores the received MR data in the storage 132. The MR data stored in the storage 132 is disposed in k-space by the controller 133. Consequently, the storage 132 stores therein k-space data.

The storage 132 stores therein the MR data received by the interface unit 131, the k-space data disposed in the k-space by the controller 133, image data generated by the image generator 136, and others. The storage 132 is a semiconductor memory device such as a random access memory (RAM) and a flash memory, a hard disk, and an optical disk, for example.

The input device 134 receives various instructions and information inputs from an operator. The input device 134 is a pointing device such as a mouse and a trackball, and an input device such as a keyboard. The display device 135 displays, under the control of the controller 133, a graphical user interface (GUI) to receive the input of imaging condition, images generated by the image generator 136, and others. The display device 135 is, for example, a display device such as a liquid crystal monitor.

The controller 133 performs an overall control of the MRI apparatus 100, and controls imaging, generation of images, display of images, and others. The controller 133 is an electronic circuit such as an integrated circuit such as an ASIC and an FPGA, a CPU, and an MPU, for example. Furthermore, the controller 133 includes, as illustrated in FIG. 1, a coefficient deriving unit 133a, an imaging condition setting unit 133b, a temperature-change predicting unit 133c, and an imaging control unit 133d. The temperature-change predicting unit 133c here predicts a temperature change in the gradient coil 103 at the time each pulse sequence is executed, based on the temperature of the gradient coil 103 and the current waveform information on the gradient magnetic field pulse, before the respective pulse sequences are executed. Furthermore, the temperature-change predicting unit 133c predicts the temperature change by separating the heat generation in the gradient coil 103 into a component equivalent to the heat generation as an electrical resistance of the gradient coil 103 and a component equivalent to the heat generation as an inductive circuit induced by the switching of the gradient coil 103. The imaging control unit 133d controls the execution of the pulse sequences in accordance with a result of the prediction. The specific content of processes of the various units will be described later in detail.

The image generator 136 reads out the k-space data from the storage 132, and performs reconstruction processing such as Fourier transformation on the read out k-space data so as to generate an image.

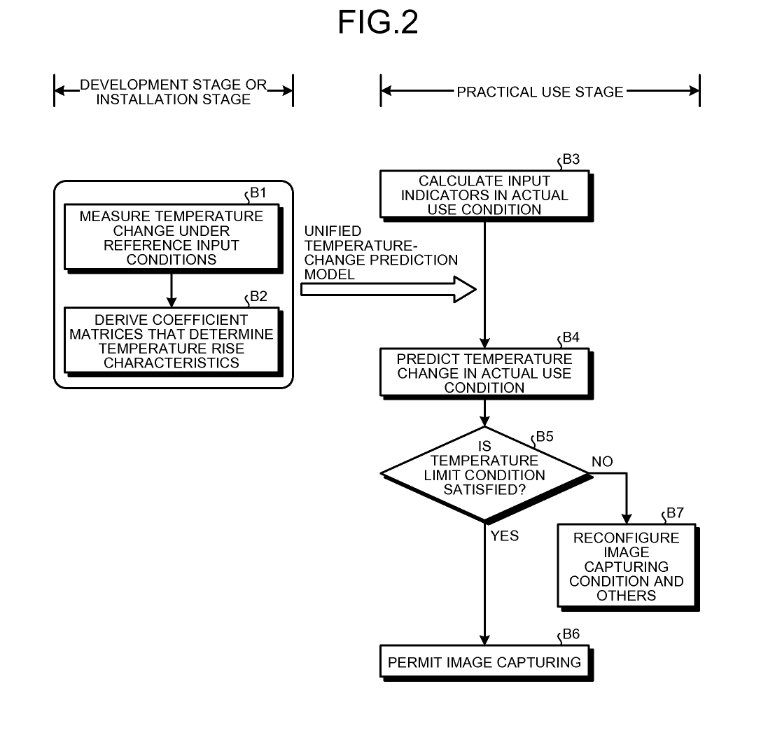

FIG. 2 is a diagram for explaining the outline of imaging control based on a temperature change prediction in the first embodiment. As illustrated in FIG. 2, in the first embodiment, a unified “temperature-change prediction model”, which includes types of pulse sequences and variations of imaging conditions, is prepared in advance, and by using this “temperature-change prediction model”, the temperature change is predicted (estimated) before various imaging (respective pulse sequences) are executed.

Here, as illustrated in FIG. 2, the consideration will be given separately to a development stage or installation stage by the manufacturer of the MRI apparatus 100, and to a practical use stage in which the MRI apparatus 100 is actually used in examinations. First, the “temperature-change prediction model” is to be derived at the development stage or installation stage of the MRI apparatus 100. Furthermore, this “temperature-change prediction model” defines the heat generation in the gradient coil 103 for each channel and the heat generation by interaction between different channels as input indicators, and is expressed by a mathematical expression that is a weighted sum of these input indicators. The “channels” correspond to three coils corresponding to the respective axes of X, Y, and Z, and the gradient coil 103 has an “X channel”, a “Y channel”, and a “Z channel”.

At the development stage or installation stage, a variety of reference imaging are performed and temperature changes are measured in various reference input conditions (B1), and by solving the simultaneous equations of the “temperature-change prediction model”, coefficient matrices in the weighted sum that determines the characteristics of temperature rise are derived (B2).

At the practical use stage, the input indicators in an actual use condition are calculated on each occasion (B3), and by applying the calculated input indicators to the above-described “temperature-change prediction model”, the temperature change in the actual use condition is predicted (B4). Subsequently, at the practical use stage, it is determined, based on the predicted temperature change, whether the execution of a pulse sequence satisfies a temperature limit condition (B5). Then, based on the result of determination, the execution of imaging is permitted as is (B6), or the reconfiguration of imaging condition, the change in the order of imaging, and others are considered (B7).

Now, the unified “temperature-change prediction model” in the first embodiment will be described first. In the first embodiment, the “temperature-change prediction model” includes a model that predicts the amount of temperature rise (hereinafter, referred to as a “temperature-rise amount model”) and a model that predicts a time constant of temperature rise (hereinafter, referred to as a “time constant model”).

The temperature-rise amount model is expressed by the following expression (1).

δT(j)=Σ_{ch}(A_{ch}^{j}×P^{ch})+Σ_{ch< >ch}, (A′_{ch,ch′}^{j}×P^{CH}×P^{ch′}) (1)

Thus, the amount of temperature rise δT(j) at a temperature measuring point (j) is obtained, with the power of each channel (P^{ch}) and a product of the power between different channels (P^{ch}×P^{ch′}) as input indicators, by performing a weighted sum of the input indicators. The power of each channel is equivalent to the heat generation in each channel, and the product of the power between different channels is equivalent to the heat generation by the interaction between the different channels. In other words, the amount of temperature rise δT(j) is obtained by performing a weighted sum of “the power of X coil”, “the power of Y coil”, “the power of Z coil”, “the product of the power of X coil and the power of Y coil”, “the product of the power of Y coil and the power of Z coil”, and “the product of the power of Z coil and the power of X coil”. In the expression (1), A_{ch}^{j} and A′_{ch,ch′}^{j} are the coefficient matrices in the weighted sum. Furthermore, in the expression (1), the representation of “ch< >ch” means that the product between the same coil (for example, the product of the power of X coil and the power of X coil) is excluded.

The time constant model is expressed by the following expression (2).

τ(j)=Σ_{ch}(B_{ch}^{j}×P^{ch})/Σ_{ch}(P^{ch}) (2)

Thus, the time constant (τ(j)) of temperature rise at the temperature measuring point (j) is obtained, with the power of each channel (P^{ch}) as an input indicator, by performing a weighted sum of the input indicator by a coefficient matrix (B_{ch}^{j}). There may be a case in which the input indicator includes the product of the power between different channels (the heat generation by the interaction between the different channels).

As in the foregoing, both the temperature-rise amount model and the time constant model define the power of each channel as an input indicator. On this point, in the first embodiment, the power of each channel (Pₜₒₜₐₗ) is considered, as expressed in the following expression (3), by separating it into a component (P_{dc}) equivalent to the heat generation as an electrical resistance (DC resistance) and a component (Pₑ) equivalent to the heat generation as an inductive circuit induced by the switching of the gradient coil 103.

Pₜₒₜₐₗ=P_{dc}+Pₑ (3)

It is known that the relation by the following expression (4) holds true among the power P, the resistance R, and the current I.

P=RI² (4)

Consequently, when the component (P_{dc}) equivalent to the heat generation as a DC resistance is expressed by using the relation of the expression (4), the following expression (5) is derived. The component (P_{dc}) equivalent to the heat generation as a DC resistance is obtained by the expression (5) for each channel, that is, for each of the X coil, the Y coil, and the Z coil.

$${P}_{dc} = {R}_{dc} ⋆ {I}_{max}^{2} ⋆ \frac{1}{T} ⋆ {\int }^{T} {\{ I ( t ) / {I}_{max} \}}^{2} d t \qquad ( 5 )$$

The item R_{dc} is the DC resistance of each channel, and is a value calculated or actually measured at the development stage or installation stage. The item Iₘₐₓ is a value of maximum current of each channel, and is a value also calculated or actually measured at the development stage or installation stage. Meanwhile, the item I(t) is a value of the current at the time t during the execution of a pulse sequence, and the item T is an execution time of the pulse sequence (for example, an execution time for one repetition time (TR) and an execution time for one pulse sequence). In the expression (5), the square of the current value I(t) is calculated by the time average of the execution time of the pulse sequence. In the expression (5), the unknown parameters to be input at the practical use stage of the MRI apparatus 100 are two parameters of the current value I(t) at the time t during the execution of a pulse sequence and the execution time T of the pulse sequence.

Furthermore, when the component (Pₑ) equivalent to the heat generation as an inductive circuit is expressed by using the relation of the expression (4), the following expression (6) is derived. The component (Pₑ) equivalent to the heat generation as an inductive circuit is obtained by the expression (6) for each channel, that is, for each of the X coil, the Y coil, and the Z coil.

$$Pe = k ⋆ {R}_{dc} ⋆ {I}_{max}^{2} ⋆ \frac{1}{T} ⋆ {\int }^{T} {\{ \frac{d ( I ( t ) / {I}_{max} )}{d t} \times h ( t ) \}}^{2} d t \qquad ( 6 )$$

In the expression (6), the term (d(I(t)/Tₘₐₓ)/dt)×h(t) represents the convolution of the time derivative of the current value d(I(t)/I)ₘₐₓ)/dt and the time response h(t) that is determined by induction. The item k is a parameter to express the amount of temperature rise by the heat generation as an inductive circuit as a relative amount with reference to the amount of temperature rise by the heat generation as a DC resistance, and is for convenience sake.

The time response h(t) is expressed by the following expression (7).

$$h ( t ) = {\sum }_{m} {C}_{m} ⋆ Exp ( - \frac{t}{{tau}_{m}} ) \qquad ( 7 )$$

As expressed in the expression (7), the time response h(t) is expressed in general by the exponential attenuation of a time constant tauₘ. The item Cₘ is a coefficient to relatively express the intensity of each component when the time response h(t) is composed of a plurality of components.

As in the foregoing, the component (P_{dc}) equivalent to the heat generation as a DC resistance is expressed by the expression (5), and the component (Pₑ) equivalent to the heat generation as an inductive circuit is expressed by the expression (6) and the expression (7). The unknown parameters to be input in the foregoing expressions at the practical use stage of the MRI apparatus 100 are two parameters of the current value I(t) at the time t during the execution of a pulse sequence and the execution time T of the pulse sequence. In other words, at the practical use stage of the MRI apparatus 100, if the pulse sequence to be executed is determined and the values of these two parameters are determined, the input indicators, that is, the component (P_{dc}) equivalent to the heat generation as a DC resistance and the component (Pₑ) equivalent to the heat generation as an inductive circuit are obtained from the expression (5), the expression (6), and the expression (7). Then, by assigning these input indicators to the expression (1) of the temperature-rise amount model and to the expression (2) of the time constant model, and by solving the expression (1) and the expression (2), the temperature rise amount δT(j) at the temperature measuring point (j) and the time constant τ(j) of temperature rise are predicted.

As expressed in the following expression (8), the temperature rise amount δT(j) of the expression (1) is modeled as it is proportionate to the respective power P of the X coil, the Y coil, and the Z coil. The power P may be any of P_{dc}, Pₑ, and Pₜₒₜₐₗ. In other words, it should be noted that, for the expressions in the foregoing, there are a number of equivalent expressions.

δT∝P(X,Y, Z) (8)

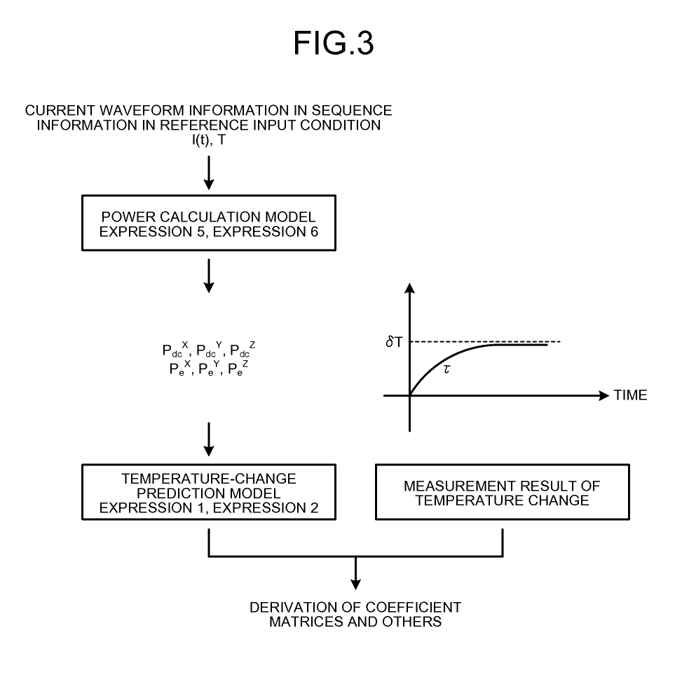

Next, the following describes the processing at the development stage or installation stage in FIG. 2, that is, the execution of a variety of reference imaging and the derivation of coefficient matrices of the “temperature-change prediction model”. FIG. 3 is a diagram for explaining the derivation of coefficient matrices in the first embodiment. At this stage, other than the coefficient matrices of the “temperature-change prediction model”, the time constant tauₘ and the parameter Cₘ in the expression (7) are unknown parameters.

The coefficient deriving unit 133a first executes a variety of reference imaging prepared in advance. The coefficient deriving unit 133a then identifies, based on the current waveform information in the sequence information in the reference input condition, two parameters of the current value I(t) and the pulse-sequence execution time T. Subsequently, the coefficient deriving unit 133a assigns the current value I(t) and the pulse-sequence execution time T to a power calculation model, that is, the expression (5) and the expression (6), and as illustrated in FIG. 3, obtains the power P of the respective channels. The coefficient deriving unit 133a then assigns the obtained power P to the expression (1) and the expression (2) and assigns the measurement result of temperature change, which is measured as a result of executing the reference imaging, to the expression (1) and the expression (2), and then solves the simultaneous equations with the coefficient matrices, the time constant tauₘ, and the parameter Cₘ as unknown parameters. Thus, as illustrated in FIG. 3, the coefficient matrices, the time constant tauₘ, and the parameter Cₘ are derived.

The coefficient deriving unit 133a needs to execute the reference imaging such that the heat generation in each channel and the heat generation by the respective interactions between different channels are to be separated. Furthermore, the coefficient deriving unit 133a needs to execute the reference imaging such that the component equivalent to the heat generation as a DC resistance and the component equivalent to the heat generation as an inductive circuit are to be separated. Moreover, the coefficient deriving unit 133a has to obtain the time constant tauₘ and the parameter Cₘ also. Consequently, the coefficient deriving unit 133a executes a variety of reference imaging while changing the coil to which the gradient magnetic field pulse is applied and the shape of the gradient magnetic field pulse, for example, and by comparing the measurement results of temperature change in respective situations, the coefficient deriving unit 133a separates the above-described elements and derives the intended unknown parameters.

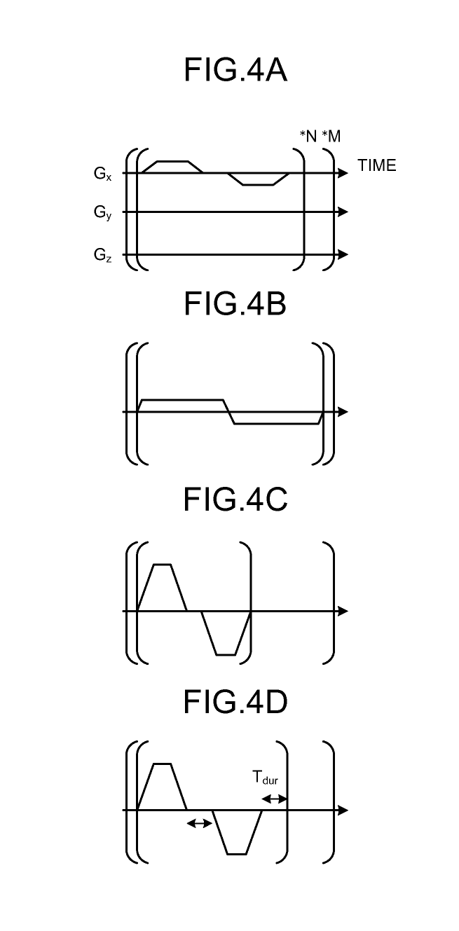

FIGS. 4A to 4D are diagrams for explaining the reference imaging in the first embodiment. The coefficient deriving unit 133a executes, as the reference imaging, a pulse sequence in which a gradient magnetic field pulse in a given shape, polarity, and time duration is repeatedly applied. For example, FIG. 4A illustrates that the coefficient deriving unit 133a drives an X coil Gₓ out of the gradient coil 103 and executes a pulse sequence in which the gradient magnetic field pulse depicted in FIG. 4A is repeatedly applied.

The double parentheses in FIG. 4A mean to indicate that the application of the gradient magnetic field pulse inside the inner parentheses is repeated N times and the whole thing, that is, the inside of the outer parentheses is repeated after a certain interval, and the number of repeats of the whole thing is M times. The same applies to FIGS. 4B, 4C, and 4D.

While the coefficient deriving unit 133a drives only the X coil Gₓ out of the gradient coil 103 in FIG. 4A, the reference imaging is not limited to this. The coefficient deriving unit 133a executes a variety of reference imaging while changing the coil to drive such as driving only a Y coil G_{y}, driving only a Z coil G_{z}, driving only the X coil Gₓ and the Y coil G_{y}, driving only the Y coil G_{y} and the Z coil G_{z}, and driving only the Z coil G_{z} and the X coil G. Thus, by comparing the respective measurement results of temperature change in a variety of reference imaging, the coefficient deriving unit 133a is able to separate the heat generation in each channel and the heat generation by the respective interactions between different channels.

Furthermore, the coefficient deriving unit 133a executes the reference imaging while changing the shape of the gradient magnetic field pulse, and by comparing the respective measuring results of temperature change in the various situations, the coefficient deriving unit 133a is able to separate the component equivalent to the heat generation as a DC resistance and the component equivalent to the heat generation as an inductive circuit. For example, when FIG. 4B is supposed to be the reference imaging to measure the temperature rise of mainly the DC resistance, FIG. 4C is the reference imaging to measure the temperature rise in which the DC resistance and inductive current comparably contribute. In FIG. 4C, as compared with FIG. 4B, the rising of the gradient magnetic field pulse is larger and the proportion taken up by switching is higher. The coefficient deriving unit 133a is able to obtain, by comparing the measurement results of the two situations, the coefficient matrix of the component equivalent to the heat generation as an inductive circuit.

Furthermore, the coefficient deriving unit 133a executes, for example, as illustrated in FIG. 4D, the reference imaging while maintaining the shape of the individual gradient magnetic field pulse but changing the time duration T_{dur} to apply the gradient magnetic field pulse of the same polarity, and by comparing the results of temperature change in the respective situations, the coefficient deriving unit 133a is able to obtain the time constant tauₘ. The coefficient deriving unit 133a further executes the reference imaging while changing the rising (a slew rate) of the gradient magnetic field pulse, and by comparing the results of temperature change in the respective situations, the coefficient deriving unit 133a is able to obtain the parameter Cₘ.

Note that the reference imaging illustrated in FIGS. 4A to 4D are mere examples. As in the foregoing, the coefficient deriving unit 133a appropriately executes a variety of reference imaging in which the shape, polarity, and time duration of the gradient magnetic field pulse are different, and by comparing the measurement results of temperature change in the respective situations, the coefficient deriving unit 133a separates the elements to determine the characteristics of temperature rise and derives the intended unknown parameters.

The derivation process of the “temperature-change prediction model” that is performed at the development stage or installation stage has been explained in the foregoing. At the practical use stage, by applying the input indicators in the actual use condition to the “temperature-change prediction model” thus derived, the temperature change in the actual use condition is predicted. Now, in the following, the prediction of temperature change at the practical use stage will be described.

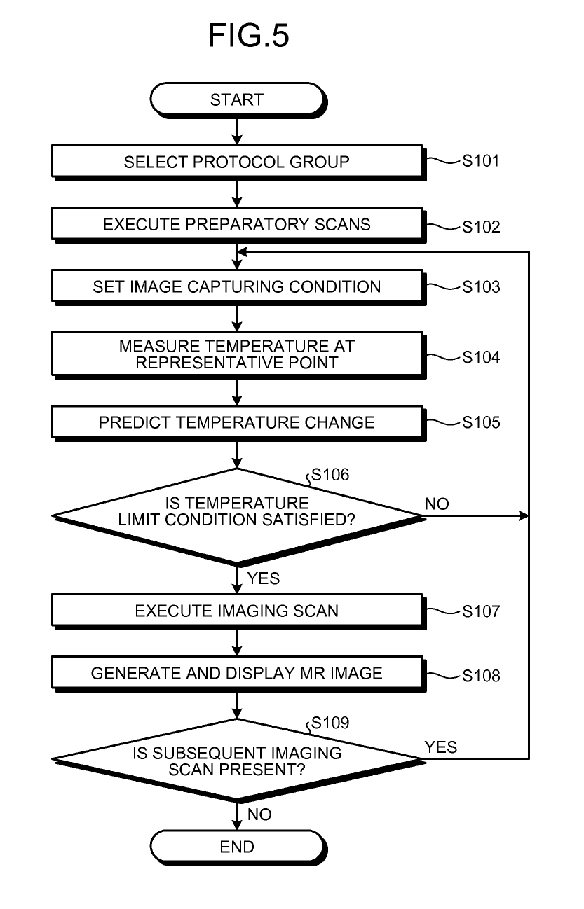

FIG. 5 is a flowchart illustrating a processing procedure of an examination performed in the first embodiment. When an examination by the MRI apparatus 100 is started, the imaging condition setting unit 133b displays a selection screen for a protocol group to be executed in the examination on the display device 135 and receives the selection of the protocol group from the operator (Step S101). The MRI apparatus 100 here may have a prepared set of protocol groups (that is, groups of pulse sequences) in which the initial values of imaging parameters are set in advance by the region of imaging and by the purpose of imaging. In the protocol group, pulse sequences of various preparatory scans and pulse sequence of one or a plurality of imaging scans are included in advance. For example, the imaging condition setting unit 133b, while presenting the protocol groups that are prepared in advance and correspond to a region of imaging and an intended purpose of imaging specified by the operator, receives the selection and changes by the operator as appropriate and determines the protocol group to be executed in the examination. The imaging condition setting unit 133b then generates sequence information in accordance with the imaging parameters of the respective protocols and sends the generated sequence information to the sequence controller 120.

Subsequently, the sequence controller 120 first executes preparatory scans in accordance with the protocol group determined at Step S101 (Step S102). The preparatory scans are the scans performed ahead of an imaging scan that acquires what is called a diagnostic MR image, and include a scan to acquire a positioning image, a scan to acquire sensitivity information about the receiving coil 109, and a scan for shimming in which the amount of correction to correct the uniformity of the static magnetic field is obtained, for example.

After the execution of such preparatory scans, one or a plurality of imaging scans are to be executed in sequence by the sequence controller 120. In the first embodiment, however, the temperature-change predicting unit 133c predicts, at the timing prior to executing each imaging scan, a temperature change on each occasion. The specific examples of imaging scan include, for example, as for the imaging scan of head, imaging by T2-weighted fast spin echo (FSE), imaging by T1-weighted spin echo (SE), imaging by three-dimensional MR angiography (MRA), and imaging by echo planar imaging (EPI).

For example, after the execution of the preparatory scans and before the execution of an imaging scan, the imaging condition setting unit 133b, as necessary, displays a setting screen for an imaging condition on the display device 135 and receives the setting of various imaging parameters included in the imaging condition from the operator (Step S103). The imaging condition setting unit 133b displays a positioning image acquired by the preparatory scans on the display device 135 and receives the setting for the imaging position and such of a diagnostic image to be acquired by the imaging scan from the operator, for example. Other than that, the imaging condition setting unit 133b can receive, at this timing, setting changes of the various imaging parameters (for example, setting changes from the initial values) from the operator. The imaging parameters are the number of matrices, TR, echo time (TE), number of slices, slice thickness, and field of view (FOV) of an MR image, for example.

Furthermore, at this timing, the temperature-change predicting unit 133c acquires the current temperature of the gradient coil 103 at the representative point from the temperature sensor 103a (Step S104), and predicts the temperature change at the time the imaging scan to be executed next is executed (step S105). For example, the temperature-change predicting unit 133c obtains, based on the current waveform information on the pulse sequence to be executed next, the current value I(t) and the pulse-sequence execution time T that are the unknown parameters. This current waveform information is generated based on the imaging parameters set at Step S103. The shape, polarity, and time duration of the gradient magnetic field pulse are determined in response to the information on the imaging position (for example, an oblique angle) and the number of matrices, for example. Consequently, the temperature-change predicting unit 133c reads out the shape, polarity, and time duration of the gradient magnetic field pulse from the current waveform information and obtains the current value I(t) and the pulse-sequence execution time T.

The temperature-change predicting unit 133c then assigns the current value I(t) and the pulse-sequence execution time T to the expression (5) and the expression (6) and obtains the power P (P_{dc}, P_{c}, and Pₜₒₜₐₗ) of the respective channels. The temperature-change predicting unit 133c further assigns the obtained power P (P_{dc}, Pₑ, Pₜₒₜₐₗ) of the respective channels to the expression (1) and the expression (2), and predicts the amount of temperature rise δT(j) at the temperature measuring point (j) and the time constant τ(j) of temperature rise. At this time, the temperature-change predicting unit 133c predicts the temperature to actually reach and the timing thereof based on the current temperature of the representative point measured at Step S104.

While a method of directly obtaining the amount of temperature rise δT(j) and the time constant τ(j) by assigning the current value I(t) and the pulse-sequence execution time T to the respective expressions has been explained, the embodiment is not limited to this, and the method may obtain the amount of temperature rise δT(j) and time constant τ(j) indirectly. For example, the temperature-change predicting unit 133c prepares in advance the dependency relation of the imaging parameters and the input indicators (the power P of each channel) in a database. The temperature-change predicting unit 133c refers to the database by using the imaging parameters set at Step S5103 and identifies the power P of the respective channels. The temperature-change predicting unit 133c then assigns the identified power P of the respective channels to the expression (1) and the expression (2) and predicts the amount of temperature rise δT(j) and the time constant τ(j).

As for the imaging parameters to store the dependency relation in the database, the parameters concerning the resolution or the time average of execution time of the pulse sequence are used, for example. As for the imaging parameters concerning the resolution, because the in-plane resolution can be obtained by FOV—Number of matrices of MR image, the FOV and the number of matrices of MR image are used, for example. As for the imaging parameters concerning the time average of execution time of the pulse sequence, the TR and the TE are used, for example.

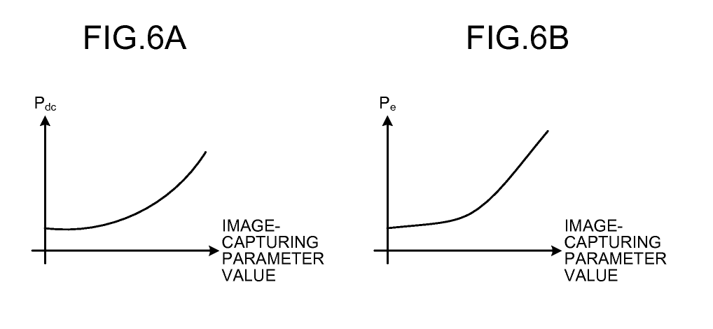

FIGS. 6A and 6B are diagrams for explaining one example of the temperature change prediction in the first embodiment. For example, as illustrated in FIG. 6A, the temperature-change predicting unit 133c prepares the dependency relation of an imaging parameter value and the power (P_{dc}) equivalent to the heat generation as a DC resistance, in a database in advance. Furthermore, as illustrated in FIG. 6B, the temperature-change predicting unit 133c prepares the dependency relation of the imaging parameter value and the power (Pₑ) equivalent to the heat generation as an inductive circuit, in the database in advance. As illustrated in FIGS. 6A and 6B, the DC resistance component and the inductive circuit component have separate dependency relations and the respective dependency relations are included in the temperature-change predicting unit 133c as the database in advance.

In the direct method in which the input indicators are calculated on each occasion, there is a merit in which an accurate prediction is ensured at all times. Meanwhile, in the indirect method in which the dependency relations are provided by the database, there is a merit in which the amount of calculation is reduced and thus a dead time at the time of changing the imaging parameter is decreased, thereby improving the response.

The temperature-change predicting unit 133c may include a database for each type of pulse sequence, for example. The temperature-change predicting unit 133c includes a database that represents the dependency relation of the imaging parameter and the power (PA equivalent to the heat generation as a DC resistance and a database that represents the dependency relation of the imaging parameter and the power (Pₑ) equivalent to the heat generation as an inductive circuit, for example. In this case, the temperature-change predicting unit 133c predicts, for each type of pulse sequence to be executed, the temperature change based on the dependency relation of the database corresponding thereto.

Furthermore, the temperature-change predicting unit 133c may include a database for each combination of a plurality of imaging parameters of pulse sequence, for example. The temperature-change predicting unit 133c includes a database that represents the dependency relation of the combination of a plurality of imaging parameter values and the power (P_{dc}) equivalent to the heat generation as a DC resistance and a database that represents the dependency relation of the combination of a plurality of imaging parameter values and the power (Pₑ) equivalent to the heat generation as an inductive circuit, for example. In this case, the temperature-change predicting unit 133c predicts, for each combination of imaging parameter values set as an imaging condition, the temperature change based on the dependency relation of the database corresponding thereto.

Referring back to FIG. 5, the temperature-change predicting unit 133c subsequently determines, based on the amount of temperature rise δT(j) and the time constant τ(j) predicted at Step S105, whether the execution of the next pulse sequence satisfies the temperature limit condition (Step S106). A gradient subsystem that includes the gradient power supply 104 and the gradient coil 103 is not capable of making the maximum current flow through all channels continuously at the same time, and thus there are various restrictions such as an upper limit of the power as a whole and an upper limit of the power for each channel. The restrictions are, based on the specifications of the gradient power supply 104 and the gradient coil 103, calculated or actually measured in advance. The temperature-change predicting unit 133c determines whether the execution of the next pulse sequence satisfies the temperature limit condition thus calculated or actually measured in advance.

If the temperature limit condition is satisfied (Yes at Step S106), the temperature-change predicting unit 133c outputs that to the sequence controller 120, and the sequence controller 120 executes the imaging scan according to the /imaging condition set at Step S103 (Step S107). As in the foregoing, the imaging parameters are set with the initial values in advance. It is assumed normally that, if the initial values are as is, it is often determined that the temperature limit condition is satisfied. When the setting change from the initial values is received from the operator at Step S103, for example, there may be a case in which the temperature limit condition is still satisfied and the imaging scan is executable in accordance with the imaging condition as intended by the operator. However, there may be a case in which the temperature limit condition is no longer satisfied as a result of the setting change.

Consequently, if the temperature limit condition is not satisfied (No at Step S106), the temperature-change predicting unit 133c outputs that to the imaging condition setting unit 133b. Then, the imaging condition setting unit 133b returns to the processing at Step S103 again, and displays the setting screen for the imaging condition on the display device 135 and receives the operation to return the imaging parameters to the initial values or to further change the imaging parameters. Such a recovery measure may be performed not necessarily via the operation of the operator. In other words, the imaging condition setting unit 133b may return the imaging parameters to the initial values automatically, for example. The imaging condition setting unit 133b can further output, to the display device 135 and other output devices, the necessary information such as warning information and the information to advise the change in the imaging parameters as appropriate.

The temperature-change predicting unit 133c then repeats the processes from Step S103 to Step S106 until the temperature limit condition is satisfied. Naturally, in the second and subsequent rounds, the step to measure the temperature of the representative point can be omitted.

When the temperature limit condition is thus satisfied (Yes at Step S106) and the imaging scan is executed (Step S107), the image generator 136, for example, generates and displays an MR image (Step S108). Furthermore, the sequence controller 120 checks for the presence of a subsequent imaging scan (Step S109). If the subsequent imaging scan is present (Yes at Step S109), the sequence controller 120 controls the process so as to return to the processing performed by the imaging condition setting unit 133b at Step S103 again. If the subsequent imaging scan, however, is not present (No at Step S109), the sequence controller 120 ends a series of processes. Subsequently, post-processing and others are performed as necessary.

As in the foregoing, in the first embodiment, a power calculation model for each channel is prepared with a current value and a pulse-sequence execution time as variables that can be derived from the imaging parameters of a pulse sequence. Furthermore, in the first embodiment, a temperature-change prediction model that predicts the amount of temperature rise in the gradient coil 103 and a time constant thereof is prepared with the power of the respective channels that are calculated by the power calculation model as input indicators. Thus, in accordance with the first embodiment, the amount of temperature rise and the time constant thereof can be predicted at the timing of actually having set the imaging parameters of pulse sequences, and the reconfiguration of imaging condition and others can be performed as necessary before the respective pulse sequences are executed. As a result, a situation can be avoided in which a normal progress of examination performed by the MRI apparatus 100 is interrupted by a rise in temperature.

Furthermore, the types of pulse sequence and the variations of imaging condition vary extensively. However, in the first embodiment, the unified temperature-change prediction that includes these variations enables an accurate temperature change prediction to be made. As a result, this can reliably protect the MRI apparatus 100, and for the operator, this can let him/her set the imaging condition without confusion.

### Modification in First Embodiment

The prediction of temperature change at the practical use stage is not limited to the above-described method. More specifically, in FIG. 5, illustrated has been the method in which the temperature change is predicted one by one for the setting change in the imaging parameters, and whether the temperature limit condition is satisfied is determined on each occasion. However, the embodiment is not limited to this. For example, the imaging condition setting unit 133b may be configured to receive the setting of imaging parameters within a range of setting limit values by defining the setting limit values of the imaging parameters based on the relation of the current waveform information on a gradient magnetic field pulse and the temperature change in the gradient coil at the time a pulse sequence according to the current waveform information is executed.

For example, the imaging condition setting unit 133b defines, based on the expression (5) and the expression (6), the setting limit values (upper limit and lower limit) of the imaging parameters beforehand. More specifically, when the power (PA equivalent to the heat generation as a DC resistance and the power (Pₑ) equivalent to the heat generation as an inductive circuit are defined in advance, the current value I(t) and the pulse-sequence execution time T can be obtained by the back calculation of the expression (5) and the expression (6), and further, the range of values that can be set for the various imaging parameters can be narrowed. In this case, the imaging condition setting unit 133b receives only the setting of the imaging condition in the range of values that can be set at Step S103, and thus the sequence controller 120 can execute the imaging scan in accordance with the imaging condition set at Step S103 as is, for example.

Moreover, the limit values of the power (P_{dc}) equivalent to the heat generation as a DC resistance and the power (Pₑ) equivalent to the heat generation as an inductive circuit may be dynamically defined by taking the measured current temperature into consideration. In this case, the limit values of the power (PA equivalent to the heat generation as a DC resistance and the power (Pₑ) equivalent to the heat generation as an inductive circuit are dynamically obtained from the current temperature, the expression (1), the for example, and then the ranges of values of the various imaging parameters that can be set are narrowed dynamically. The imaging condition setting unit 133b thus receives only the setting changes of the imaging parameters within the dynamically narrowed range.

### Second Embodiment

A second embodiment will be described. In the first embodiment, the MRI apparatus 100 cools the gradient coil 103 by the cooling device 125. In the second embodiment, the relation with the cooling by the cooling device 125 is further taken into consideration.

First, the cooling device 125 is explained in addition. The cooling device 125 circulates, under the control of the sequence controller 120, the refrigerant at a given temperature to the gradient coil 103 by branching into the respective pathways for the X coil, the Y coil, and the Z coil. The cooling device 125 includes a mechanism (for example, a heat exchanger) that adjusts the temperature of the refrigerant, and when a target temperature is received from the sequence controller 120, the cooling device 125 adjusts the temperature of the refrigerant to be at this temperature. The cooling device 125 further adjusts the flow rate of the refrigerant.

Thus, at the practical use stage of the MRI apparatus 100, the imaging is performed while the gradient coil 103 is cooled by the cooling device 125. Consequently, it is desirable that the dependency relation with the cooling condition by the cooling device 125 be reflected on the coefficient matrices and others of the “temperature-change prediction model” that are derived at the development stage or installation stage described in the first embodiment. More specifically, the coefficient deriving unit 133a, at the development stage or installation stage, executes a variety of reference imaging while varying the cooling condition (the temperature, flow rate, and others of the refrigerant) by the cooling device 125 and derives the intended unknown parameters for each cooling condition, for example.

As in the foregoing, if the dependency relation of the coefficient matrices and others of the “temperature-change prediction model” with the cooling condition by the cooling device 125 is known in advance, the prediction of temperature change at the practical use stage can be made more accurately. For example, at the time the temperature change is predicted at Step S105 in FIG. 5, the temperature-change predicting unit 133c can predict the temperature change based on the relation with the cooling condition of the gradient coil 103 also. In other words, the temperature-change predicting unit 133c predicts the temperature change by using the “temperature-change prediction model” of the coefficient matrices and others corresponding to the cooling condition to be applied.

Furthermore, when it is found that the temperature does not rise much as a result of predicting the temperature change by using the “temperature-change prediction model” of the coefficient matrices and others corresponding to the cooling condition to be applied, for example, the imaging control unit 133d may change the cooling condition by using the result.

More specifically, the change in temperature also influences the uniformity of magnetic field, and in terms of image quality, it is preferable that the temperature does not vary much (for example, not being overcooled). Thus, as a result of the prediction by the temperature-change predicting unit 133c, if the temperature is predicted to be lowered (or maintained at a low temperature) lower than necessary at the time the cooling condition to be applied is applied as is, the imaging control unit 133d can perform control such that the temperature changes between pulse sequences are averaged to some extent (in other words, the image quality between the pulse sequences is averaged to some extent) by daring to change the cooling condition. As a consequence, the power consumption can also be reduced.

### Other Embodiments

The embodiments are not to be limited to the foregoing embodiments.

While the methods of predicting the temperature change prior to executing each of the pulse sequences have been explained in the foregoing embodiments, the timing of predicting the temperature change is not necessarily limited to only prior to executing each of the pulse sequences and the prediction may be made in other timing. For example, when all of the pulse sequences are executed, the temperature-change predicting unit 133c may also collectively predict the temperature change before the pulse sequences are executed.

Furthermore, the temperature-change predicting unit 133c may predict the temperature change before a specific pulse sequence out of a plurality of pulse sequences is executed, for example. The specific pulse sequence here is a pulse sequence that has been predetermined as a specific type of pulse sequence for which the temperature change is expected to be large, for example.

Moreover, while the MRI apparatus 100 has been explained to include the coefficient deriving unit 133a in the foregoing embodiments, the embodiments are not limited to this. That is, as in the foregoing, the processing performed by the coefficient deriving unit 133a is done at the development stage or installation stage of the MRI apparatus 100. Thus, the coefficient deriving unit 133a may be provided on a testing device or the like separately from the MRI apparatus 100, and the parameters of the “temperature-change prediction model” and a database that represents the dependency relation of the imaging parameter values and the power, which are necessary to predict the temperature change, may be derived by the testing device or the like, for example. The temperature-change predicting unit 133c of the MRI apparatus 100 holds the parameters and the database thus derived separately by the testing device or the like and predicts the temperature changes. Specific Numerical Values and Order of Processes

The specific numerical values and the order of processes (for example, the processing procedure illustrated in FIG. 5) illustrated in the foregoing embodiments are mere examples in principle.

### Computer Program

The instructions indicated in the processing procedure illustrated in the foregoing embodiments can be executed based on a computer program that is software. The instructions described in the foregoing embodiments are stored as a computer executable program in a magnetic disk, an optical disc, a semiconductor memory, or a recording medium similar to the foregoing. When the computer reads in the computer program from the recording medium and makes the CPU execute, based on the computer program, the instructions described in the computer program, the same functions as those of the MRI apparatus 100 in the embodiments can be implemented. Furthermore, when the computer acquires or reads in the computer program, the computer may acquire or read it via a network.

In accordance with the magnetic resonance imaging apparatus and an imaging control method thereof in at least one of the embodiments in the foregoing, a situation can be avoided in which a normal progress of examination is interrupted by a rise in temperature.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a predicting unit that predicts a temperature change in a gradient coil at a time a pulse sequence is executed, based on temperature of the gradient coil and current waveform information on a gradient magnetic field pulse, before the pulse sequence is executed; and
an imaging control unit that controls execution of the pulse sequence in accordance with a result of the prediction, wherein
the predicting unit predicts the temperature change by separating heat generation in the gradient coil into a component equivalent to heat generation as an electrical resistance of the gradient coil and a component equivalent to heat generation as an inductive circuit induced by switching of the gradient coil.

2. The magnetic resonance imaging apparatus according to claim 1, wherein the predicting unit predicts an amount of temperature rise in the gradient coil and a time constant of temperature rise as the temperature change.

3. The magnetic resonance imaging apparatus according to claim 1, wherein the predicting unit predicts an amount of temperature rise in the gradient coil by performing weighted sum on power of each of coils orthogonal to one another out of a plurality of coils of the gradient coil and products of power between different coils.

4. The magnetic resonance imaging apparatus according to claim 1, wherein
the predicting unit predicts the temperature change by using a temperature-change prediction model prepared at a development stage or an installation stage of the magnetic resonance imaging apparatus, and
the temperature-change prediction model is derived at the development stage or the installation stage by executing reference imaging in which at least one of shape, polarity, and time duration of a gradient magnetic field pulse is different and comparing measurement results of temperature change in each reference imaging.

5. The magnetic resonance imaging apparatus according to claim 1, wherein the predicting unit further predicts the temperature change based on relation with a cooling condition of the gradient coil.

6. The magnetic resonance imaging apparatus according to claim 5, wherein the imaging control unit changes the cooling condition of the gradient coil based on a result of prediction of temperature change by the predicting unit.

7. The magnetic resonance imaging apparatus according to claim 1, wherein the predicting unit predicts the temperature change based on respective dependency relations of an imaging parameter of the pulse sequence with the component equivalent to heat generation as an electrical resistance and the component equivalent to heat generation as an inductive circuit.

8. The magnetic resonance imaging apparatus according to claim 7, further comprising:
a storage that stores therein information indicative of the respective dependency relations of the imaging parameter with the component equivalent to heat generation as an electrical resistance and the component equivalent to heat generation as an inductive circuit for each type of the pulse sequence, wherein
the predicting unit predicts the temperature change for each type of the pulse sequence based on the information.

9. The magnetic resonance imaging apparatus according to claim 1, wherein the predicting unit predicts the temperature change based on respective dependency relations of a combination of a plurality of imaging parameters of the pulse sequence with the component equivalent to heat generation as an electrical resistance and the component equivalent to heat generation as an inductive circuit.

10. The magnetic resonance imaging apparatus according to claim 1, wherein when a plurality of pulse sequences are executed in sequence, the predicting unit predicts the temperature change before each pulse sequence is executed.

11. The magnetic resonance imaging apparatus according to claim 1, wherein when a plurality of pulse sequences are executed in sequence, the predicting unit collectively predicts the temperature change before the pulse sequences are executed.

12. The magnetic resonance imaging apparatus according to claim 1, wherein when a plurality of pulse sequences are executed in sequence, the predicting unit predicts the temperature change before a specific pulse sequence out of the pulse sequences is executed.

13. A magnetic resonance imaging apparatus comprising:
an imaging condition setting unit that receives setting of imaging parameters of a pulse sequence; and
an imaging control unit that controls execution of the pulse sequence in accordance with the imaging parameters, wherein
the imaging condition setting unit controls the setting of imaging parameters based on a relation of current waveform information on a gradient magnetic field pulse and temperature change in a gradient coil at a time the pulse sequence is executed in accordance with the current waveform information.

14. The magnetic resonance imaging apparatus according to claim 13, wherein the imaging condition setting unit defines setting limit values of imaging parameters based on the relation and receives the setting of imaging parameters within a range of the setting limit values.

15. An imaging control method of a magnetic resonance imaging apparatus, the method comprising:
predicting a temperature change in a gradient coil at a time a pulse sequence is executed, based on temperature of the gradient coil and current waveform information on a gradient magnetic field pulse, before the pulse sequence is executed; and
controlling execution of the pulse sequence in accordance with a result of the prediction, wherein
the temperature change is predicted by separating heat generation in the gradient coil into a component equivalent to heat generation as an electrical resistance of the gradient coil and a component equivalent to heat generation as an inductive circuit induced by switching of the gradient coil.
